(19) United States
(12) Patent Application Publication
(10) Pub. No.: US 2025/0110411 A1
(43) Pub. Date: Apr. 3, 2025

(54) METHOD FOR FORMING A PATTERN ON A SUBSTRATE

(71) Applicant: ASM IP Holding B.V., Almere (NL)

(72) Inventors: Kishan Ashokbhai Patel, Leuven (BE); Ikhlas Rahmat, Leuven (BE); Yoann Tomczak, Leuven (BE); David Kurt de Roest, Leuven (BE)

(21) Appl. No.: 18/900,231

(22) Filed: Sep. 27, 2024

Related U.S. Application Data
(60) Provisional application No. 63/586,953, filed on Sep. 29, 2023.

(51) Int. Cl. G03F 7/00; C23C 16/24; C23C 16/455; G03F 7/16; H01L 21/033

(52) U.S. Cl. CPC G03F 7/70033; C23C 16/24; C23C 16/45525; C23C 16/45536; G03F 7/167; G03F 7/70866; H01L 21/033

(57) ABSTRACT

A method for forming a pattern on a substrate disclosed. The method comprising, providing an Extreme Ultraviolet (EUV) lithography system having an exposure chamber, providing a substrate to the exposure chamber, the substrate comprising a patternable layer, the patternable layer comprising a photosensitive surface termination; and exposing the substrate to EUV radiation while exposing the patternable layer to a reactive gas, thereby forming a pattern on the patternable layer, comprising exposed areas and unexposed areas, the unexposed areas comprising the photosensitive surface termination and the exposed areas comprising an altered surface termination.

### CROSS-REFERENCE TO RELATED APPLICATION(S)

This Application claims the benefit of U.S. Provisional Application 63/586,953 filed on Sep. 29, 2023, the entire contents of which are incorporated herein by reference.

### FIELD OF INVENTION

The present disclosure relates to a method for forming patterns on a substrate, particularly to a method in which some parts of a film's surface are EUV radiated with O₂/H₂ environment so that the exposed parts may be selectively patterned.

### BACKGROUND OF THE DISCLOSURE

Devices in the integrated circuits (ICs) are scaling down rapidly. Fabrication of such devices requires multiple steps, and one of the main bottlenecks in the fabrication is lithography step.

Extreme ultraviolet (EUV) lithography technique is becoming one of the mainstream methods for the fabrication of semiconductor devices with the critical dimensions below 20 nm, which helps in solving the problem with resolution of the lithography tool.

However, multiple lithography steps are still required to achieve smaller dimensions. This is mainly firstly because of the limited resolution of photolithography tool and secondly due to inability to have robust resist to define such small feature in single exposure.

This disclosure presents a solution for the second problem by exposing the surface of a thin film (<5nm thick) using EUV radiation.

After modifying the surface, a hard mask can be selectively deposited on either un/exposed surface of the thin film.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a method for forming a pattern on a substrate, the method comprising, providing an Extreme Ultraviolet (EUV) lithography system having an exposure chamber, providing a substrate to the exposure chamber, the substrate comprising a patternable layer, the patternable layer comprising a photosensitive surface termination, and exposing the substrate to EUV radiation while exposing the patternable layer to a reactive gas, thereby forming a pattern on the patternable layer, comprising exposed areas and unexposed areas, the unexposed areas comprising the photosensitive surface termination and the exposed areas comprising an altered surface termination.

In at least one aspect, the patternable layer comprises a Silicon containing Anti-Reflective Coating (SiARC) film.

In at least one aspect, the SiARC film is deposited using Plasma Enhanced Atomic Layer Deposition (PEALD) or thermal Atomic Layer Deposition (ALD).

In at least one aspect, the SiARC film is deposited with a temperature between 50° C. and 200° C.

In at least one aspect, the reactive gas comprises O₂/H₂.

In at least one aspect, the photosensitive surface termination comprises methyl group (CH₃).

In at least one aspect, the altered surface termination comprises hydroxide (OH).

In at least one aspect, the altered surface termination is hydrophilic.

In at least one aspect, the partial pressures of O₂ and H₂ range between 1×10⁻⁶ and 1×10⁻⁴ mbar, respectively.

In at least one aspect, the total pressure of O₂ and H₂ ranges between 1×10⁻⁶ mbar and 1×10⁻⁴ mbar.

In at least one aspect, the photosensitive surface termination is hydrophobic.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an EUV lithography system with a SiARC film on a substrate according to an embodiment of the present disclosure.

FIG. 2 illustrates an EUV radiation on a SiARC film with a reactant gas environment according to an embodiment of the present disclosure.

FIG. 3 illustrates an example of the usage of the present disclosure, a hard mask selectively deposited on the EUV-exposed area after EUV-exposure.

FIG. 4 illustrates a flowchart of the present disclosures order.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

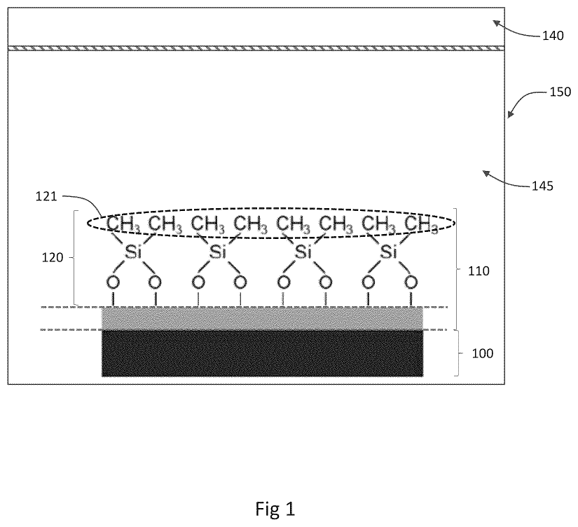

Referring to FIG. 1, a photoactive polymer layer 120 is formed on a top surface of a substrate 110 and the substrate 110 is placed on top of a susceptor 100.

An EUV lithography system 150 contains the photoactive polymer layer 120, the substrate 110 and the susceptor 100 inside of it.

The EUV lithography system 150 may comprise an EUV chamber 140 where EUV light is generated and an exposure chamber 145 where the substrate 110 is exposed to the generated EUV light.

The photoactive polymer layer 120 may include a silicon-containing anti-reflective coating (SiARC) film and this may be formed on top of the substrate 110 by plasma enhanced atomic layer deposition (PEALD) or thermal atomic layer deposition (thermal ALD).

SiARC film may be a Silicon OxyCarbide (SiOC) film terminated with methyl group (CH₃) 121 attached to Si as shown in FIG. 1 and the SiARC film may be deposited with a temperature between 50° C. and 200° C.

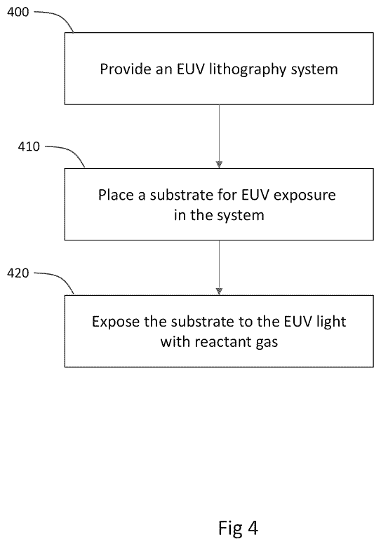

This disclosure's patterning method is disclosed in the chart illustrated in FIG. 4.

First, an EUV lithography system 150 which comprises a EUV lamp chamber 140 and an exposure (reaction) chamber 145 may be prepared (400 in FIG. 4).

The EUV chamber 140 may contain one or more EUV lamps for generating EUV light and the exposure chamber 145 which may contain a substrate 110.

Once the EUV lithography system may be ready, a substrate 110 may be placed in the exposure chamber 145. The substrate 110 may comprise a patternable layer 120 (410 in FIG. 4).

The patternable layer 120 may comprise a photosensitive surface termination and the photosensitive surface termination may comprise a methyl group (CH₃) 121. This patternable layer 120 may be an SiARC film.

Due to the methyl group 121 in the substrate 110 and the substrate 110 would be hydrophobic in nature. This hydrophobicity of the substrate 110, which comes from the patternable layer 120's photosensitive surface termination (methyl group) 121, may need to be changed for patterning the substrate 110.

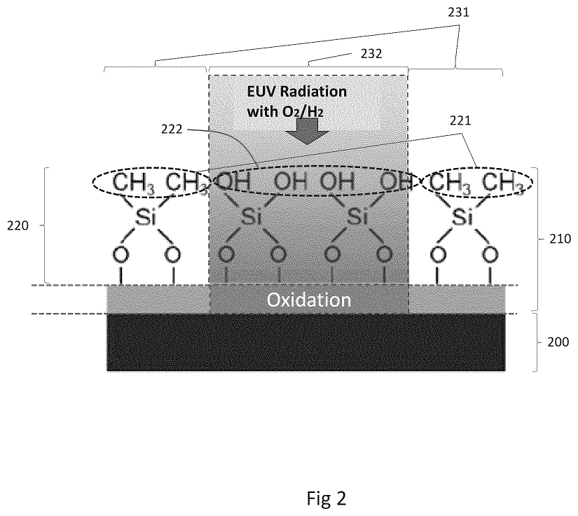

The change for patterning may come from the EUV exposure illustrated in FIG. 2.

In FIG. 2, the substrate 210 may be placed on the susceptor 200 and the substrate 210 may comprise a patternable layer 220 that comprises a photosensitive surface termination 221. The EUV lamp chamber 140 (in FIG. 1) may selectively emit EUV radiation to the substrate 210.

In the substrate 210, the part 232 may be exposed to the EUV radiation and the part 231 may not be EUV-exposed and this EUV radiation happens in O₂/H₂ environment (420).

With the EUV radiation with O₂/H₂ environment, the patternable layer 220's photosensitive surface termination 221 is replaced with other termination.

For example, the photosensitive surface termination 221, i.e. methyl group (CH₃), may be replaced with hydroxide (OH) as shown in FIG. 2. This replacement of surface termination would make the surface of the patternable layer (SiARC film) from hydrophobic into hydrophilic.

As shown above, this disclosure presents a method to change surface of a target layer (patternable layer) from hydrophobic into hydrophilic by using oxidizing or reducing environment during EUV exposure to the target.

For making a suitable environment for oxidation or reduction, the partial pressure of O₂ gas and the partial pressure of H₂ gas in the chamber may be between 1×10⁻⁶ and 1×10⁻⁴ mbar, respectively. In other cases, the total pressure of O₂ and H₂ gas may be between 1×10⁻⁶ and 1×10⁻⁴ mbar.

The EUV-exposed area 232 and unexposed area 231 may have different surface terminations in the patternable layer 220. In FIG. 2, the unexposed area 231 remains still to be hydrophobic while the exposed area 232 may be changed into hydrophilic.

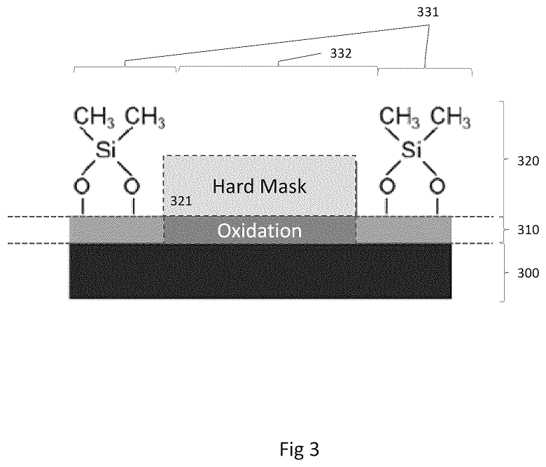

FIG. 3 illustrates a hard mask 321 deposited on the substrate 310 after EUV exposure done like in FIG. 2. The unexposed area 331 may be unchanged but the hard mask 321 may be deposited selectively on the exposed area 332 using water based thermal oxidation process at low temperature less than 150° C.

The above-described arrangement of method is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A method for forming a pattern on a substrate, the method comprising:
providing an Extreme Ultraviolet (EUV) lithography system having an exposure chamber;
providing a substrate to the exposure chamber, the substrate comprising a patternable layer, the patternable layer comprising a photosensitive surface termination; and
exposing the substrate to EUV radiation while exposing the patternable layer to a reactive gas, thereby forming a pattern on the patternable layer, comprising exposed areas and unexposed areas, the unexposed areas comprising the photosensitive surface termination and the exposed areas comprising an altered surface termination.

2. The method according to the claim 1, wherein the patternable layer comprises a Silicon containing Anti-Reflective Coating (SiARC) film.

3. The method according to the claim 2, wherein the SiARC film is deposited using Plasma Enhanced Atomic Layer Deposition (PEALD) or thermal Atomic Layer Deposition (ALD).

4. The method according to the claim 3, wherein the SiARC film is deposited with a temperature between 50° C. and 200° C.

5. The method according to the claim 1, wherein the reactive gas comprises O₂/H₂.

6. The method according to the claim 1, wherein the photosensitive surface termination comprises methyl group (CH₃).

7. The method according to the claim 1, wherein the altered surface termination comprises hydroxide (OH).

8. The method according to the claim 1, wherein the altered surface termination is hydrophilic.

9. The method according to the claim 5, wherein the partial pressures of O₂ and H₂ range between 1×10⁻⁶ and 1×10⁻⁴ mbar, respectively.

10. The method according to the claim 5. wherein the total pressure of O₂ and H₂ ranges between 1×10⁻⁶ and 1×10⁻⁴ mbar.

11. The method according to the claim 1. wherein the photosensitive surface termination is hydrophobic.
